(19) United States
(12) Patent Application Publication
(10) Pub. No.: US 2011/0089447 A1
(43) Pub. Date: Apr. 21, 2011

(54) LIGHT-EMITING DEVICE CHIP WITH MICRO-LENSES AND METHOD FOR FABRICATING THE SAME

(76) Inventors: Wu-Cheng Kuo, Hsinchu City (TW); Chi-Xiang Tseng, Hsinchu City (TW)

(21) Appl. No.: 12/581,731

(22) Filed: Oct. 19, 2009

(51) Int. Cl. H01L 33/00; H01L 21/78

(52) U.S. Cl. 257/98; 438/29; 257/99; 438/33; 257/E21.599; 257/E33.067; 257/E33.066

(57) ABSTRACT

A light-emitting device (LED) chip is disclosed. The LED chip includes a body having a light extraction surface. The body includes semiconductor layers including an n-type region and a p-type region. A plurality of micro-lenses is directly on the light extraction surface of the body. A pair of bond pads is electrically connected to the n-type and p-type regions, respectively. A method for fabricating the LED chip and an LED package with the LED chip are also disclosed.

### BACKGROUND OF THE INVENTION

1. Field of the Invention

The invention relates to a light-emitting device (LED) and more particularly to LED chip with micro-lenses and methods for fabricating the same.

2. Description of the Related Art

Light-emitting device (LED) chips (dice) are solid-state light sources and have been known for years. The LED chips are based on the recombination of electron-hole pairs in a pn-junction in a semiconductor material which is forward-biased. Advantages of LED chips compared with traditional lamps are lower power consumption and longer lifespan. To increase an LED chip's reliability and lower its energy consumption, increasing light-emitting efficiency thereof is required.

Light-emitting efficiency is affected by light extraction efficiency of the LED chip. The light extraction efficiency is determined by the structure, the light absorption index and refractive index of LED chips. Accordingly, to further increase the light-emitting efficiency of LED chips, the light extraction efficiency thereof must be increased.

In conventional LED chips, the emitted light cannot be effectively extracted from the chip due to the total internal reflection phenomenon, thereby resulting in low light extraction efficiency. Therefore, an LED chip has been disclosed, wherein the surface of the LED chip is roughened to decrease light reflection and increase light scattering therein, thereby increasing light extraction efficiency of the LED chip. For example, an LED chip with a roughened surface can be accomplished by a natural lithography or wet etching process. Such a technology is referred as surface texturing. However, since the roughened surface exhibits an irregular arrangement, it is difficult to control the light-emitting angle of the LED chip.

Therefore, there is a need to develop a novel LED chip capable of increasing light extraction efficiency without the above problems.

### BRIEF SUMMARY OF THE INVENTION

A detailed description is given in the following embodiments with reference to the accompanying drawings. A light-emitting device (LED) chip, a method for fabricating LED chips and an LED package with an LED chip are provided. An embodiment of a light-emitting device chip is disclosed. The light-emitting device chip comprises a body having a light extraction surface. The body comprises semiconductor layers comprising an n-type region and a p-type region. A plurality of micro-lenses is directly on the light extraction surface of the body. A pair of bond pads is electrically connected to the n-type and p-type regions, respectively.

An embodiment of a method for fabricating LED chips comprises providing a wafer comprising at least two light-emitting device regions separated by at least one dicing lane, in which each light-emitting device region has a light extraction surface and comprises semiconductor layers comprising an n-type region and a p-type region. A pair of bond pads is electrically connected to the n-type and p-type regions of the semiconductor layers of each light-emitting device region, respectively. A plurality of micro-lenses is formed on the light extraction surface of each light-emitting device region. The wafer is diced along the dicing lane to form individual light-emitting device chips.

Another embodiment of a light-emitting device package comprises a carrier substrate and a light-emitting device chip electrically connected to the carrier substrate. The light-emitting device chip comprises a body having a light extraction surface, a plurality of micro-lenses, and a pair of bond pads. The body comprises semiconductor layers comprising an n-type region and a p-type region. The plurality of micro-lenses is directly on the light extraction surface of the body. A pair of bond pads is electrically connected to the n-type and p-type regions, respectively.

### BRIEF DESCRIPTION OF DRAWINGS

The invention can be more fully understood by reading the subsequent detailed description and examples with references made to the accompanying drawings, wherein:

FIGS. 1 to 4 are cross sections of various exemplary embodiments of a light-emitting device (LED) chip according to the invention;

FIGS. 5A to 5D are cross sections of an exemplary embodiment of a method for fabricating LED chips according to the invention;

FIG. 6 is a cross section of an exemplary embodiment of an LED package according to the invention; and

FIGS. 7A to 7C are cross sections of an exemplary embodiment of a method for fabricating an LED package according to the invention.

### DETAILED DESCRIPTION OF INVENTION

The following description is of the best-contemplated mode of carrying out the invention. This description is provided for the purpose of illustrating the general principles of the invention and should not be taken in a limiting sense. The scope of the invention is best determined by reference to the appended claims.

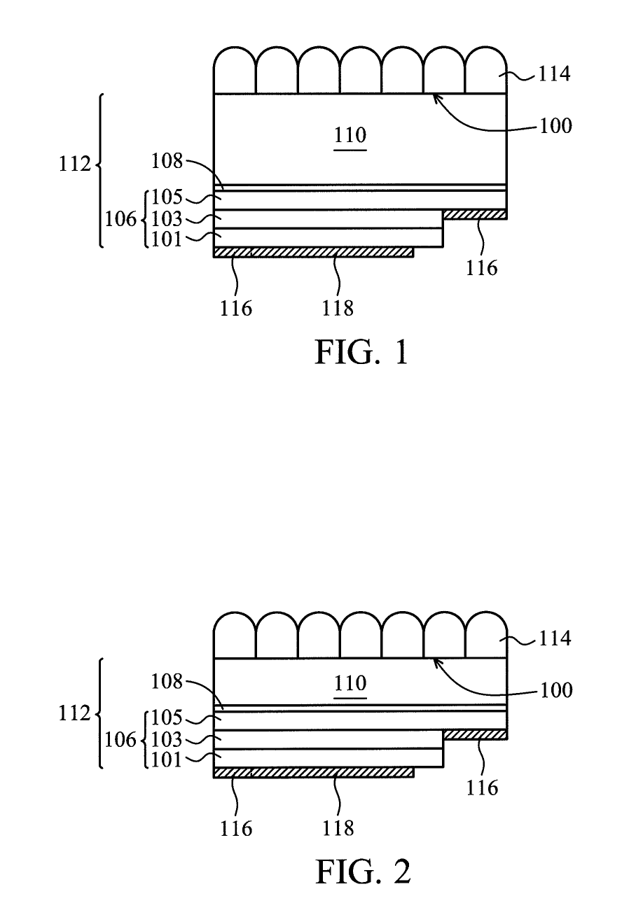

FIGS. 1 to 4 are cross sections of various exemplary embodiments of a light-emitting device (LED) chip according to the invention. Elements in FIGS. 2 to 4 that are the same as those in FIG. 1 are labeled with the same reference numbers as in FIG. 1 and are not described again for brevity. Referring to FIG. 1, the LED chip can be a red, green, blue, or white LED chip, which comprises a body 112 having a light extraction surface 100, a plurality of micro-lenses 114, and a pair of bond pads 116. In the embodiment, the body may comprise semiconductor layers 106 and a sapphire substrate 110 with a thickness of about 90 μm to 150 μm thereon. The semiconductor layers 106 may be epitaxial layers comprising GaAsP, GaAs, GaP, GaN, AlGaN, AlGaAs, AlGaInP, or other ternary or quaternary III-V group compound semiconductor materials. Moreover, the semiconductor layers 106 comprise a p-type region 101, an n-type region 105 and an active region 103 interposed therebetween. Since the lattice constant of the semiconductor layers 106 does not match that of the sapphire substrate 110, a buffer layer 108, such as AlN or GaN, is interposed between the semiconductor layers 106 and the sapphire substrate 110. Note that although FIG. 1 shows that the n-type region 105 is above the active region 103 and the p-type region 101 is under the active region 103, it can be understood that the n-type region 105 may be under the active region 103 and the p-type region 101 may be above the active region 103. In another embodiment, the sapphire substrate 110 on the semiconductor layers 106 may have a thickness of about 30 μm to 50 μm, so as to reduce the optical path for the light emitted from the active region 103 to the light extraction surface 100, as shown in FIG. 2.

The pair of bond pads 116 is connected to the p-type region 101 and the n-type region 105, respectively. In the embodiment, a current spreading layer 118 is electrically connected to one of the pair of bond pads 116. In one embodiment, the current spreading layer 118 is formed of a material the same as that of the bond pad 116 electrically connected thereto. Moreover, the current spreading layer 118 is disposed on the p-type region 101 of the semiconductor layers 106 and the bond pad 116 is connected to the p-type region 101 of the semiconductor layers 106.

The plurality of micro-lenses 114 is periodically arranged on the light extraction surface 100 of the body 112. Moreover, the plurality of micro-lenses 114 is directly on the surface of the sapphire substrate 110. The plurality of micro-lenses 114 may comprise glue, silicone or sol-gel glass. In some embodiments, the plurality of micro-lenses 114 formed of glue, silicone or sol-gel glass may comprise a fluorescent material therein. In the embodiment, each micro-lens 114 has a three-facet pyramid, four-facet pyramid, hexagonal pyramid or spherical pyramid shape. In order to simplify the diagram, only an exemplary micro-lens 114 with a shape of spherical pyramid is depicted. Since the plurality of micro-lenses 114 with periodical arrangement can effectively reduce the total internal reflection phenomenon, a majority of light emitted from the active region 103 of the semiconductor layers 106 can be directly transmitted to the outside by the plurality of micro-lenses 114 from the light extraction surface 100. Accordingly, the light extraction efficiency of the LED chip can be enhanced.

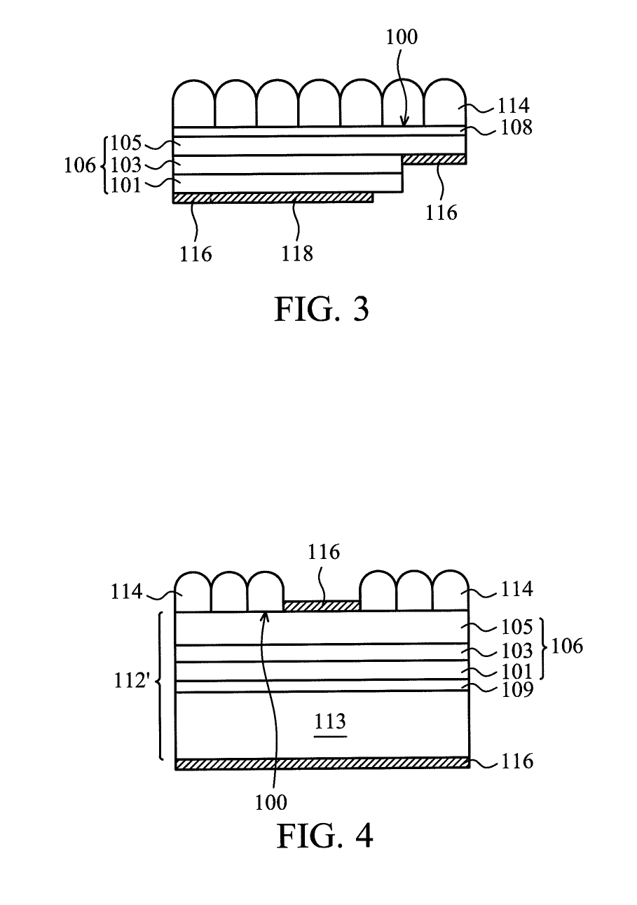

Referring to FIG. 3, the body may comprise the semiconductor layers 106 and a buffer layer 108 without the sapphire substrate 110 thereon. In the embodiment, the plurality of micro-lenses 114 is periodically and directly arranged on the light extraction surface 100 of the body. Since no sapphire substrate is disposed on the semiconductor layers 106, the optical path for the light emitted from the active region 103 of the semiconductor layers 106 to the light extraction surface 100 can be reduced to further improve the light extraction efficiency. Moreover, the entire LED chip thickness can also be reduced.

Referring to FIG. 4, the body 112′ may comprise the semiconductor layers 106, a conductive substrate 113, and a conductive bonding layer 109 interposed therebetween. Also, the semiconductor layers 106 comprise a p-type region 101, an n-type region 105 and an active region 103 interposed therebetween. In one embodiment, the conductive bonding layer 109 comprises a mirror layer (not shown) therein for reflecting the light emitted from the active region 103 of the semiconductor layers 106. The conductive substrate 113 may be metal or silicon. One of the pair of bond pads 116 is disposed on the semiconductor layers 106. For example, the bond pad 116 disposed on the semiconductor layers 106 is connected to the n-type region 105 of the semiconductor layers 106. A current spreading layer (not shown) may be disposed on the n-type region 105 of the semiconductor layers 106 and formed of a material the same as the bond pad 116 that is connected to the n-type region 105 of the semiconductor layers 106. The other pad 116 is disposed under the conductive substrate 11 so as to be connected to the p-type region 101 of the semiconductor layers 106. The plurality of micro-lenses 114 is directly on the light extraction surface 100 of the body 112′ and surrounds the bond pad 116 connected to the n-type region 105 of the semiconductor layers 106.

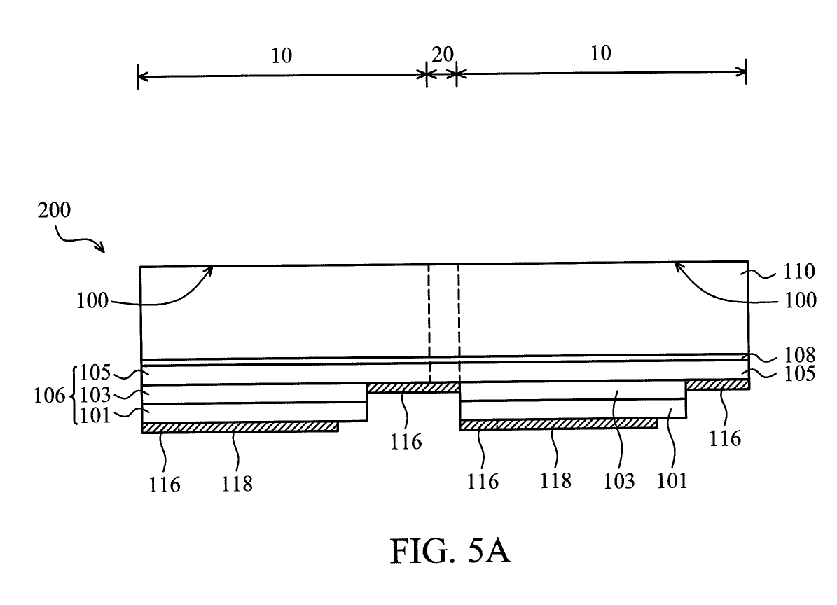

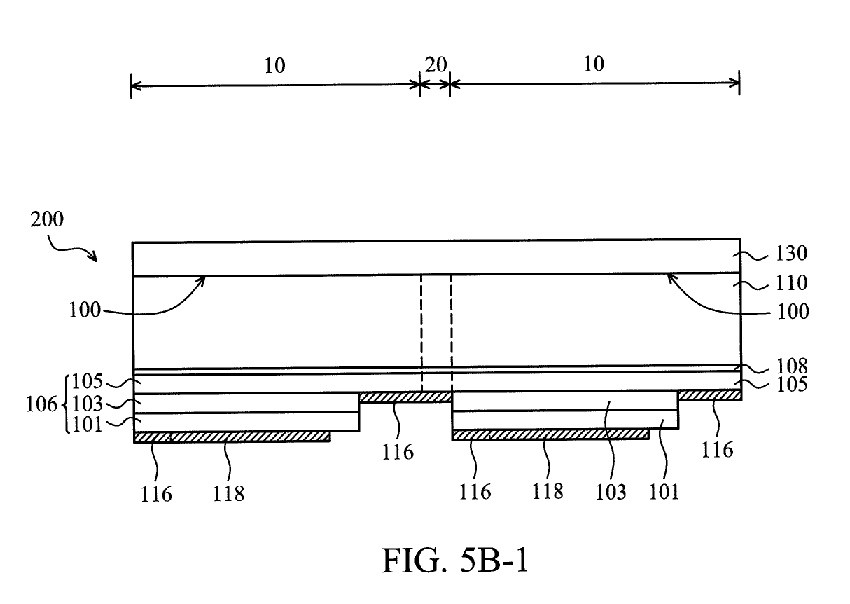

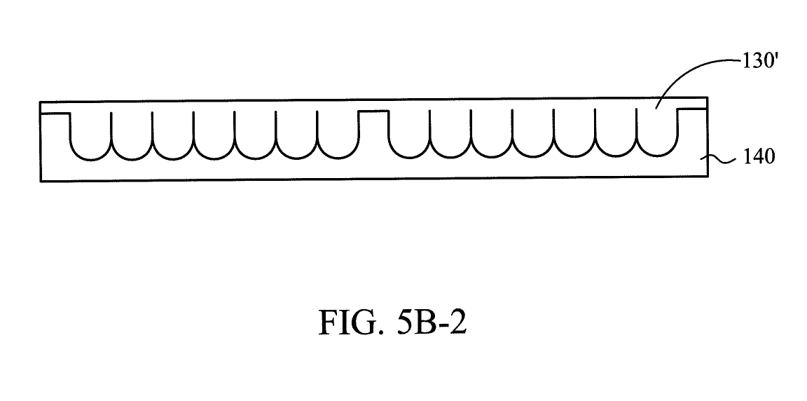

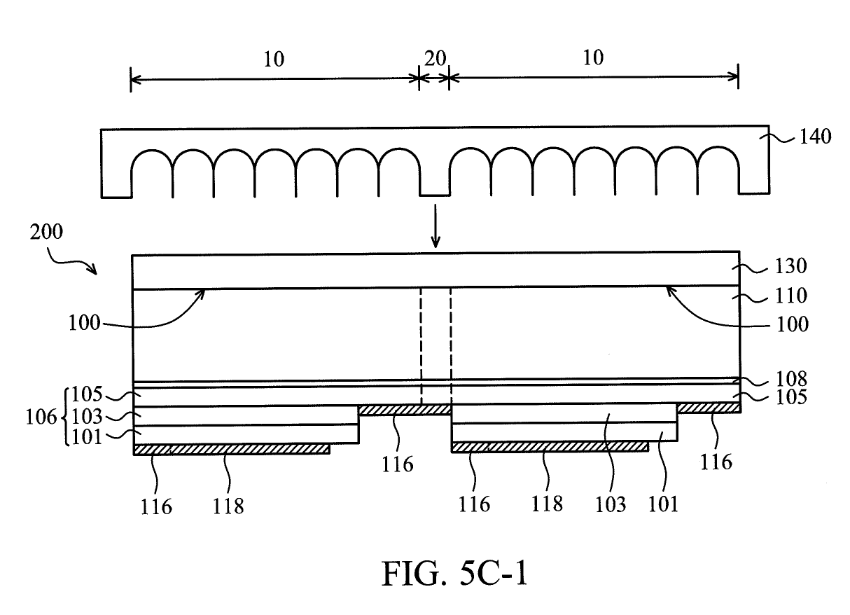

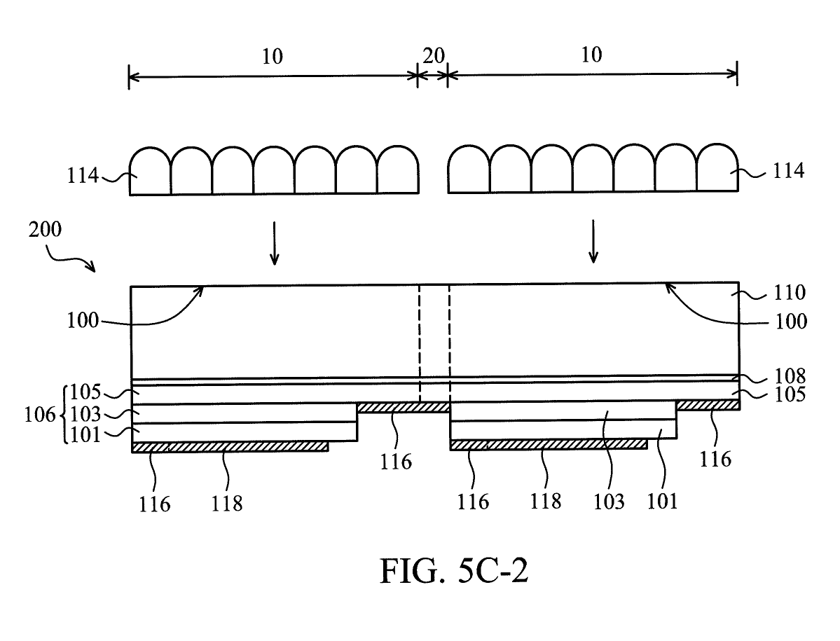

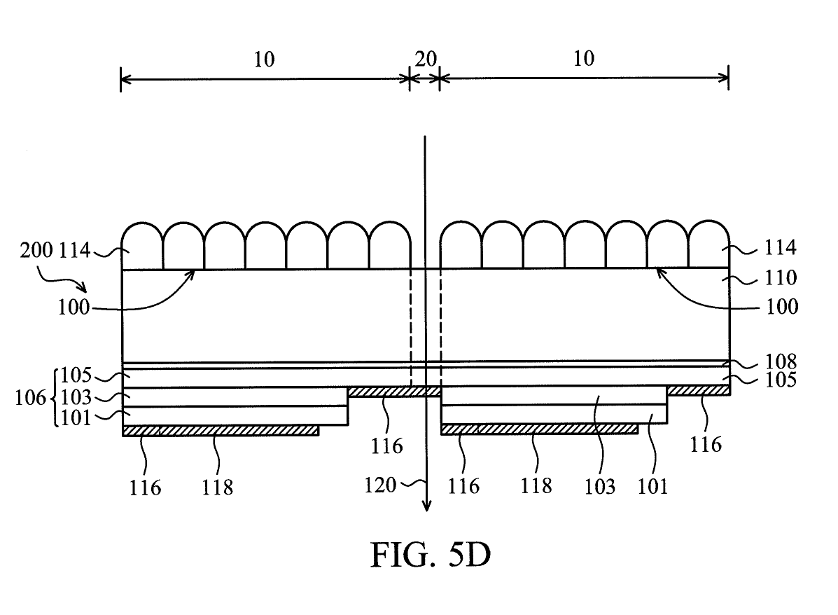

Referring to FIGS. 5A to 5D, which are cross sections of an exemplary embodiment of a method for fabricating LED chips according to the invention. Elements in FIGS. 5A to 5D that are the same as those in FIG. 1 are labeled with the same reference numbers as in FIG. 1 and are not described again for brevity. In FIG. 5A, a wafer 200 comprising at least two light-emitting device regions 10 separated by at least one dicing lane 20 is provided. In the embodiment, each light-emitting device region 10 has a body having a light extraction surface 100 and comprises semiconductor layers 106 and an overlying sapphire substrate 110, in which a buffer layer 108 is interposed between the semiconductor layers 106 and the sapphire substrate 110. Moreover, a pair of bond pads 116 is formed on the semiconductor layers 106 to electrically connect n-type and p-type regions 105 and 101 separated by an active region 103, respectively. Also, each light-emitting device region 10 may comprise a current spreading layer 118 disposed on the p-type region 101 of the semiconductor layers 106 and formed of a material the same as that of the bond pad 116 that is connected to the p-type region 101 of the semiconductor layers 106.

Next, a plurality of micro-lenses is formed on the light extraction surface 100 of each light-emitting device region 10. In one embodiment, the sapphire substrate 110 may be thinned prior to formation of the plurality of micro-lenses 114. For example, the sapphire substrate 110 may be thinned to a thickness of about 30 μm to 50 μm.

Referring to FIGS. 5B-1 and 5C-1, which illustrates an embodiment for the formation of the plurality of micro-lenses. In FIG. 5B-1, a micro-lens material 130 covers the light extraction surface 100 of the light-emitting device region 10. In the embodiment, the micro-lens material 130 comprises glue, silicone or sol-gel glass. In some embodiments, the micro-lens material 130 comprises glue, silicone or sol-gel glass having a fluorescent material formed therein. Next, in FIG. 5C-1, the micro-lens material 130 is molded by a mold 140 to form a plurality of micro-lenses therein. A plurality of micro-lenses 114 is formed on the light extraction surface 100 of each light-emitting device region 10 after removal of the mold 140, as shown in FIG. 5D.

Referring to FIGS. 5B-2 and 5C-2, which illustrates another embodiment for the formation of the plurality of micro-lenses. Elements in FIGS. 5B-2 and 5C-2 that are the same as those in FIGS. 5B-1 and 5C-1 are labeled with the same reference numbers as in FIGS. 5B-1 and 5C-1 and are not described again for brevity. In FIG. 5B-2, a micro-lens material 130′ is molded by a mold 140, to form a plurality of micro-lenses therein and corresponding to the each light-emitting device region 10. Next, in FIG. 5C-2, after removal of the mold 140, a plurality of micro-lenses 114 is formed and then is adhered onto the light extraction surface 100 of each light-emitting device region 10 by an adhesive layer (not shown). Thereafter, the plurality of micro-lenses 114 is formed on the light extraction surface 100 of each light-emitting device region 10, as shown in FIG. 5D.

Referring to FIG. 5D, after formation of the plurality of micro-lenses 114, the wafer 200 is diced 120 (as indicated by the arrow within the dicing lane 20) along the dicing lane 20 to form individual light-emitting device chips, as shown in FIG. 1. Note that the LED chips shown in FIGS. 2 to 4 may also be formed by the method similar or the same as that for formation of the LED chip shown in FIG. 1.

According to the aforementioned embodiments, the plurality of micro-lenses 114 is directly on the light extraction surface 100 of the LED chip. Compared to the conventional LED chip, light extraction efficiency of the LED chip with micro-lenses can be enhanced for increasing the light-emitting efficiency. Moreover, since the plurality of micro-lenses 114 can be formed with periodical arrangement by molding, the light-emitting angle of the LED chip with micro-lenses can be more easily controlled when compared to the conventional LED chip with a roughened surface formed by a natural lithography or wet etching process.

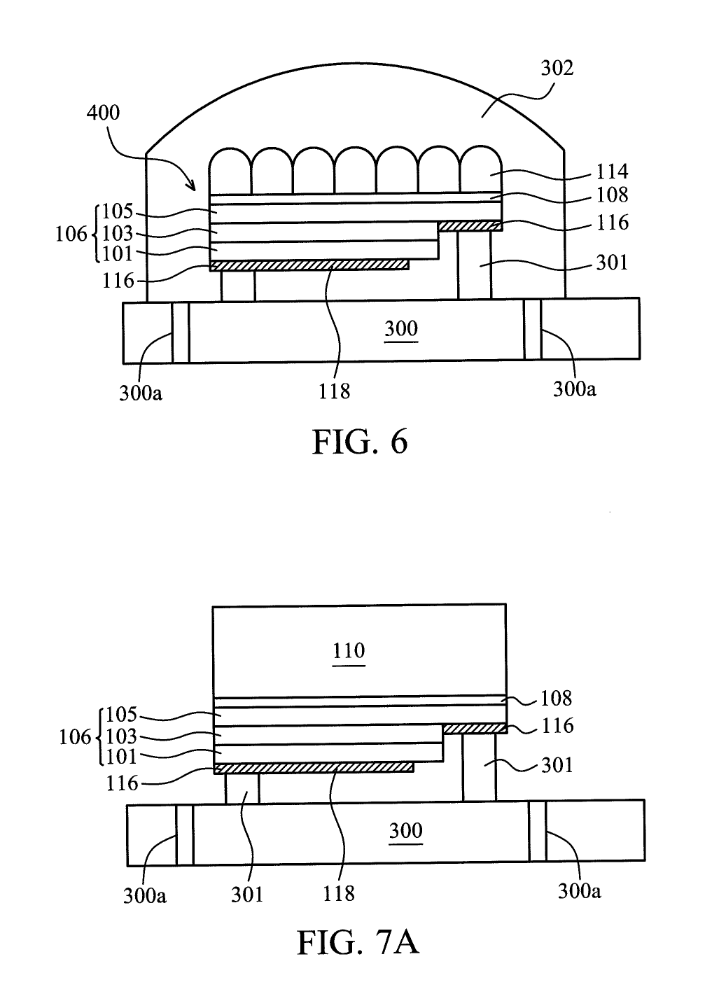

Referring to FIG. 6, which is a cross section of an exemplary embodiment of an LED package according to the invention. Elements in FIG. 6 that are the same as those in FIG. 3 are labeled with the same reference numbers as in FIG. 3 and are not described again for brevity. The LED package comprises a carrier substrate 300 and an LED chip 400 electrically connected to the carrier substrate 300. The carrier substrate 300 may be a lead frame or a ceramic or silicon substrate. In the embodiment, the LED chip 400 has a structure the same as that shown in FIG. 3. In some embodiments, the LED chip 400 may have a structure the same as that shown in FIG. 1, 2, or 4. Bumps 301 formed of gold, solder, alloy or other bump materials well known in the art are interposed between the pair of bonding pads 116 and the carrier substrate 300 for electrical connection between the carrier substrate 300 and the LED chip 400. Moreover, the carrier substrate 300 has at least one through substrate via (TSV) 300a formed therein, so as to electrically connect the LED chip 400 to an external circuit (not shown). In the embodiment, a lens 302 may be disposed on the carrier substrate 300, such that the LED chip 400 is capped by the lens 302. In this case, the lens 302 has a refractive index that is less than that of the plurality of micro-lenses 114 of the LED chip 400. For example, the lens 302 may comprise silicone with a refractive index of about 1.5, and the plurality of micro-lenses 114 may comprise sol-gel glass with a refractive index of about 2. As a result, the brightness of the LED package can be increased.

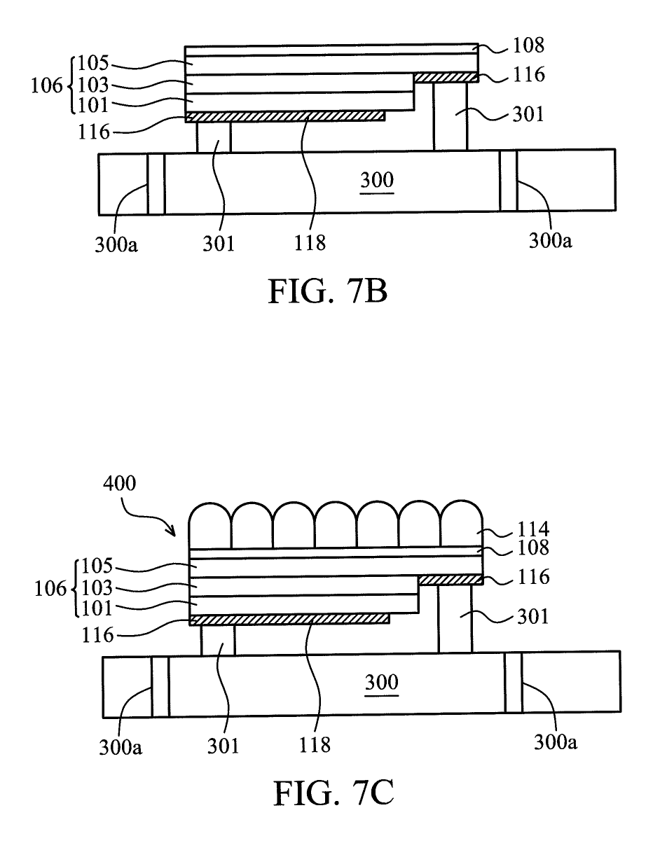

FIGS. 7A to 7C are cross sections of an exemplary embodiment of a method for fabricating an LED package according to the invention. Elements in FIGS. 7A to 7C that are the same as those in FIGS. 1, 3 and 6 are labeled with the same reference numbers as in FIGS. 1, 3 and 6 and are not described again for brevity. Referring to FIG. 7A, a carrier substrate 300 having at least one TSV 300a formed therein is provided. An LED structure is bonded onto the carrier substrate 300 by bumps 301. In the embodiment, the LED structure is the same as that shown in FIG. 1 except for the micro-lenses.

Referring to FIG. 7B, the sapphire substrate 110 of the LED chip 400 are removed from the underlying buffer layer 108 and semiconductor layers 106 by laser liftoff (LLO) technology. After removal of the sapphire layer 110, a plurality of micro-lenses 114 is formed on the buffer layer 108 and semiconductor layers 106 by, for example, a method similar as that shown in FIGS. 5B-1 to 5C-1 or FIGS. 5B-2 to 5C-2, thereby forming an LED chip 400 with micro-lenses on the carrier substrate 300, as shown in FIG. 7C. Thereafter, a lens 302 is formed on the carrier substrate 300, such that the LED chip 400 is capped by the lens 302. As a result, an LED package is completed, as shown in FIG. 6.

According to the aforementioned embodiments, since the LED chip 400 has micro-lenses 114 to enhance the light extraction efficiency thereof, the light-emitting efficiency of the LED package can be increased. Moreover, since the lens 302 can have a refractive index less than that of the plurality of micro-lenses 114, the brightness of the LED package can be further increased.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light-emitting device chip, comprising:
a body having a light extraction surface, comprising semiconductor layers comprising an n-type region and a p-type region;
a plurality of micro-lenses directly on the light extraction surface of the body; and
a pair of bond pads electrically connected to the n-type and p-type regions, respectively.

2. The light-emitting device chip of claim 1, wherein the body further comprises a sapphire substrate interposed between the semiconductor layer and the plurality of micro-lenses.

3. The light-emitting device chip of claim 1, wherein the body further comprises a conductive substrate, wherein the semiconductor layer is interposed between the conductive substrate and the plurality of micro-lenses.

4. The light-emitting device chip of claim 3, wherein the conductive substrate comprises metal or silicon.

5. The light-emitting device chip of claim 1, wherein the semiconductor layers are epitaxial layers.

6. The light-emitting device chip of claim 1, further comprising a current spreading layer electrically connected to one of the pair of bond pads.

7. The light-emitting device chip of claim 1, wherein the plurality of micro-lenses comprises glue, silicone or sol-gel glass having a fluorescent material formed therein.

8. The light-emitting device chip of claim 1, wherein each micro-lens has a three-facet pyramid, four-facet pyramid, hexagonal pyramid or spherical pyramid shape.

9. A method for fabricating light-emitting device chips, comprising:
providing a wafer comprising at least two light-emitting device regions separated by at least one dicing lane, wherein each light-emitting device region has a light extraction surface and comprises semiconductor layers comprising an n-type region and a p-type region;
electrically connecting a pair of bond pads to the n-type and p-type regions of the semiconductor layer of each light-emitting device region, respectively;
forming a plurality of micro-lenses on the light extraction surface of each light-emitting device region; and
dicing the wafer along the dicing lane to form individual light-emitting device chips.

10. The method of claim 9, wherein the formation of the plurality of micro-lenses comprises:
forming a micro-lens material on the light extraction surface of the each light-emitting device region;
molding the micro-lens material by a mold, to form the plurality of micro-lenses; and
removing the mold from the plurality of micro-lenses.

11. The method of claim 10, wherein the micro-lens material comprises glue, silicone or sol-gel glass having a fluorescent material formed therein.

12. The method of claim 9, wherein the formation of the plurality of micro-lenses on the light extraction surface of each light-emitting device region comprises:
molding a micro-lens material by a mold to form the plurality of micro-lenses corresponding to each light-emitting device region;
removing the mold from the plurality of micro-lenses; and
adhering the plurality of micro-lenses onto the light extraction surface of the each light-emitting device region by an adhesive layer.

13. The method of claim 12, wherein the micro-lens material layer comprises glue, silicone or sol-gel glass having a fluorescent material formed therein.

14. The method of claim 9, wherein each light-emitting device region of the wafer further comprises a sapphire substrate on the semiconductor layer.

15. The method of claim 1, further forming a current spreading layer electrically connected to one of the pair of bond pads at each light-emitting device region.

16. A light-emitting device package, comprising:
a carrier substrate; and
a light-emitting device chip electrically connected to the carrier substrate, wherein the light-emitting device chip comprises:
a body having a light extraction surface, comprising semiconductor layers comprising an n-type region and a p-type region;
a plurality of micro-lenses directly on the light extraction surface of the body; and
a pair of bond pads electrically connected to the n-type and p-type regions, respectively.

17. The light-emitting device package of claim 16, further comprising a lens disposed on the carrier substrate to cap the light-emitting device chip.

18. The light-emitting device package of claim 17, wherein the plurality of micro-lenses has a refractive index greater than that of the lens.

19. The light-emitting device package of claim 18, wherein the plurality of micro-lenses comprises sol-gel glass and the lens comprises silicone.

20. The light-emitting device package of claim 16, wherein the carrier substrate comprises at least one through substrate via to electrically connect the light-emitting device chip to an external circuit.
